(19) United States
(12) Patent Application Publication
(10) Pub. No.: US 2024/0213172 A1
(43) Pub. Date: Jun. 27, 2024

(54) SEMICONDUCTOR DEVICE AND METHOD OF FABRICATING THE SAME

(71) Applicant: United Microelectronics Corp., Hsinchu (TW)

(72) Inventor: Chia-Chang Hsu, Kaohsiung City (TW)

(73) Assignee: United Microelectronics Corp., Hsinchu (TW)

(21) Appl. No.: 18/181,559

(22) Filed: Mar. 10, 2023

(30) Foreign Application Priority Data
Dec. 27, 2022 (CN) 202211685202.5

(51) Int. Cl. H01L 23/544; H10B 61/00; H10B 63/00

(52) U.S. Cl. CPC H01L 23/544; H10B 61/00; H10B 63/80; H01L 2223/54426

(57) ABSTRACT

A semiconductor device includes a dielectric layer, a stop layer, a via and a memory device. The dielectric layer is located on a substrate. The stop layer is located on the dielectric layer. The via extends in the stop layer and the dielectric layer. The memory device is disposed on the via and electrically connected to the via.

### CROSS-REFERENCE TO RELATED APPLICATION

This application claims the priority benefit of China application serial no. 202211685202.5, filed on Dec. 27, 2022. The entirety of the above-mentioned patent application is hereby incorporated by reference herein and made a part of this specification.

### BACKGROUND

### Technical Field

The present disclosure relates to an integrated circuit and a method of fabricating the same, and particularly relates to a semiconductor device and a method of fabricating the same.

### Description of Related Art

With the rapid development of technology, the size of a semiconductor device is getting smaller and smaller. During the fabrication of a semiconductor device, alignment marks are often used to align front layers. However, the alignment marks may be damaged during the fabricating process, resulting in insufficient depths. The detected signals from the damaged alignment marks cannot provide sufficient contrast, so precise alignment cannot be performed.

### SUMMARY

The embodiments of the present disclosure provide a semiconductor device and a fabricating method thereof, in which the conductive layer of the alignment mark has a groove with a sufficient depth, so that the detected signal has sufficient contrast.

According to an embodiment of the present disclosure, a semiconductor device includes a dielectric layer, a stop layer, a via and a memory device. The dielectric layer is located on a substrate. The stop layer is located on the dielectric layer. The via extends in the stop layer and the dielectric layer. The memory device is disposed on the via and electrically connected to the via.

According to another embodiment of the present disclosure, a method of fabricating a semiconductor device includes the following steps. A first dielectric layer is formed on a substrate. A stop layer is formed on the first dielectric layer. An via opening and a trench for an alignment mark are formed in the stop layer and the first dielectric layer. A conductive material is formed on the substrate, filling up the via opening and filling in the trench. A planarization process is performed to remove the conductive material above the stop layer, so as to form a via in the via opening and form a conductive layer in the trench, wherein the conductive layer in the trench has a groove therein. A memory device is formed on the via.

Based on the above, in an embodiment of the present disclosure, a stop layer disposed on the dielectric layer can avoid or reduce the polishing loss of the conductive layer of the alignment mark. Accordingly, the conductive layer of the alignment mark has a groove with a sufficient depth, so that the detected signal has sufficient contrast.

In order to make the above-mentioned features and advantages of the present disclosure more comprehensible, the following specific embodiments are described in detail together with the accompanying drawings.

### BRIEF DESCRIPTION OF THE DRAWINGS

FIG. 1 to FIG. 9 are cross-sectional views of a method of fabricating a semiconductor device according to an embodiment of the present disclosure.

### DESCRIPTION OF THE EMBODIMENTS

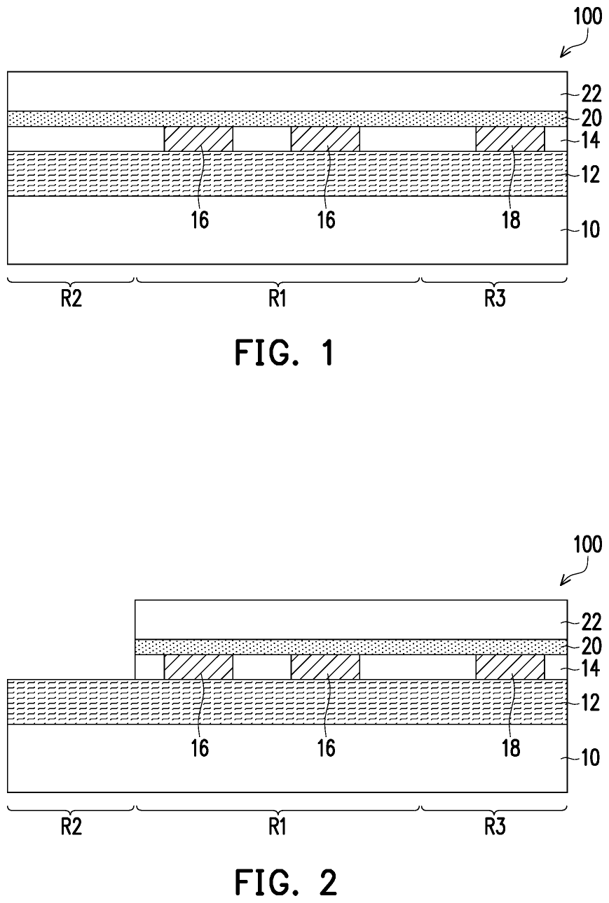

FIG. 1 to FIG. 9 are cross-sectional views of a method of fabricating a semiconductor device according to an embodiment of the present disclosure.

Referring to FIG. 1, the method of fabricating a semiconductor device 100 according to an embodiment of the present disclosure includes the following steps. A substrate 10 is provided. The substrate 10 includes a bulk semiconductor substrate, such as a bulk silicon substrate, or a semiconductor-on-insulator (SOI) substrate. The substrate 10 includes a first region R1, a second region R2 and a third region R3. The first area R1 is, for example, a memory device region. The second region R2 is, for example, an alignment mark region. The alignment mark region may be in a scribe line region. The third area R3 is, for example, a logic region.

In some embodiments, a device layer 12 is further formed on the substrate 10. The device layer 12 may include an active component, a passive component or a combination thereof. The active component may include a transistor, a diode, or the like. The passive component may include a capacitor, an inductor, or the like. The transistor can be an N-type metal oxide semiconductor (NMOS) transistor, a P-type metal oxide semiconductor (PMOS) transistor or a complementary metal oxide semiconductor device (CMOS). In some embodiments, the active component or the passive component is formed in the first region R1 and/or the third region R3 of the substrate 10. In some other embodiments, the active component or the passive component is formed in the first region R1, the second region R2 and/or the third region R3 of the substrate 10.

Referring to FIG. 2, conductive lines 16 and 18 and a dielectric layer 14 are formed on the substrate 10. The conductive lines 16 and 18 include tungsten, copper or a combination thereof. The dielectric layer 14 includes silicon oxide, undoped silicon glass, phosphosilicate glass, borophosphosilicate glass, a low dielectric constant material, an ultra-low dielectric constant material layer or a combination thereof. A contact (not shown) may also be included between the conductive lines 16 and 18 and the device layer 12. The contact is electrically connected to the device layer 12 and the conductive lines 16 and 18.

In some embodiments, the method of forming the conductive lines 16, 18 and the dielectric layer 14 is described in the following steps, but the disclosure is not limited thereto. A conductive material is formed on the device layer 12. The conductive material includes tungsten.

Then, lithography and etching processes are performed to the conductive material, so as to form one or more conductive lines 16 in the first region R1 and one or more conductive lines 18 in the third region R3, respectively. Afterwards, a dielectric material (not shown) is formed to cover the conductive lines 16, 18 and the device layer 12. Thereafter, an etching back or chemical mechanical planarization process is performed to the dielectric material, so as to form the dielectric layer 14. In some embodiments, the top surfaces of the conductive lines 16 and 18 are coplanar with the top surface of the dielectric layer 14.

In some other embodiments, the method of forming the conductive lines 16, 18 and the dielectric layer 14 is described in the following steps. A dielectric layer 14 is formed on the device layer 12. Then, conductive lines 16 and 18 are formed in the dielectric layer 14 by a damascene process. The damascene process includes performing lithography and etching processes to form trenches (not shown) in the dielectric layer 14. Afterwards, a conductive material is formed on the dielectric layer 14, filling up the trenches. The conductive material includes copper. Thereafter, a chemical mechanical planarization process is performed to the conductive material, so as to form conductive lines 16 and 18.

Afterwards, a stop layer 20 and a dielectric layer 22 are formed on the conductive lines 16 and 18 and the dielectric layer 14. The material of the stop layer 20 is different from the dielectric layer 14 or the dielectric layer 22. The stop layer 20 includes nitrogen doped SiC (NDC), silicon nitride, aluminum oxide or a combination thereof. The dielectric layer 22 includes silicon oxide, such as silicon oxide formed by using tetraethylsiloxane (TEOS) as a gas source. The thickness of the stop layer 20 ranges from 150 angstroms to 300 angstroms, for example. The thickness of the dielectric layer 22 ranges from 1,000 angstroms to 2,000 angstroms, for example.

Referring to FIG. 2, lithography and etching processes are performed to pattern the dielectric layer 22, the stop layer 20, and the dielectric layer 14, so as to remove the dielectric layer 22, the stop layer 20, and the dielectric layer 14 in the second region R2 and expose the device layer 12 in the second region R2. The etching process includes a dry etching, a wet etching or a combination thereof.

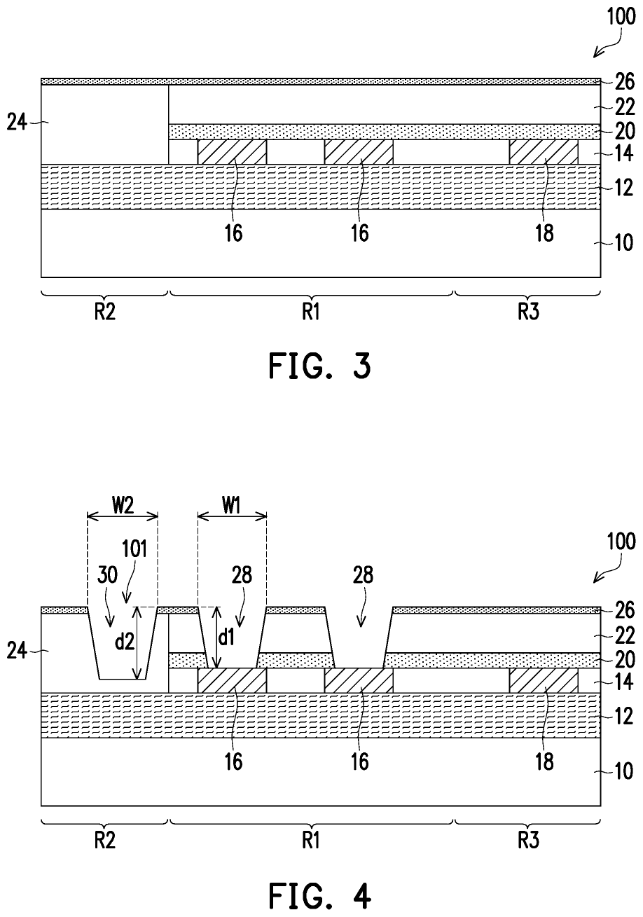

Referring to FIG. 3, a dielectric layer 24 is formed on the second region R2 of the substrate 10. The method of forming the dielectric layer 24 includes forming a dielectric material on the substrate 10. The dielectric material includes silicon oxide formed by using tetraethylsiloxane (TEOS) as a gas source. Thereafter, an etching back or chemical mechanical planarization process is performed to the dielectric material, so as to form the dielectric layer 24. In some embodiments, the top surface of dielectric layer 24 is coplanar with the top surface of dielectric layer 14. The thickness of the dielectric layer 24 is greater than the sum of the thicknesses of the dielectric layer 22 and the stop layer 20.

Thereafter, a stop layer 26 is formed on the substrate 10. The stop layer 26 may have a single-layer or multiple-layer structure. The material of the stop layer 26 includes nitrogen-doped silicon carbide, silicon nitride, silicon oxide or a combination thereof.

Referring to FIG. 4, lithography and etching processes are performed to pattern the stop layer 26, the dielectric layer 24, the dielectric layer 22, and the stop layer 20 to form a via opening 28 in the first region R1, and form a trench 30 for an alignment mark 101 in the second region R2. The etching process includes a dry etching process, a wet etching process or a combination thereof. The etching process can be a single-stage etching process or a multi-stage etching process. In some embodiments, a multi-stage etching process is used. During the main etching process of a first-stage etching, the etch stop layer 26 and the dielectric layers 22 and 24 are etched. When the stop layer 20 in the first region R1 is exposed, the stop layer 20 can be used as an etch stop layer because the etching rate of the stop layer 20 is lower than the etching rate of the dielectric layer 24. During the over-etching process of the first-stage etching, the etching rate of the stop layer 20 in the first region R1 is relatively low, while the dielectric layer 24 in the second region R2 is further etched because the etching rate of the dielectric layer 24 is greater than the etching rate of the stop layer 20. Afterwards, a second-stage etching process is performed to etch and remove the stop layer 20, so as to form one or more via openings 28 in the first region R1 and a trench 30 in the second region R2. The etchant used in the second-stage etching may be different from that the etchant used in the first-stage etching. The via opening 28 and the trench 30 may have vertical sidewalls perpendicular to the surface of the substrate 10 or have inclined sidewalls.

In an embodiment of the present disclosure, the width W2 and the depth d2 of the trench 30 in the second region R2 are larger than the width W1 and the depth d1 of the via opening 28 in the first region R1. For brevity, the widths W1 and W2 both refer to upper widths.

In some embodiments, the ratio of the width W2 of the trench 30 to the width W1 of the via opening 28 is greater than 10, for example, 10-20; the ratio of the depth d2 of the trench 30 to the depth d1 of the via opening 28 is greater than 1.5. For example, the width W2 of the trench 30 is 1 micron, and the depth d2 is from 1,500 angstroms to 1,800 angstroms; the width W1 of the via opening 28 is 65 nm, and the depth d1 is from 800 angstroms to 900 angstroms. In some embodiments, the height of the bottom surface of the trench 30 is between the top surface and the bottom surface of the conductive lines 16 or 18.

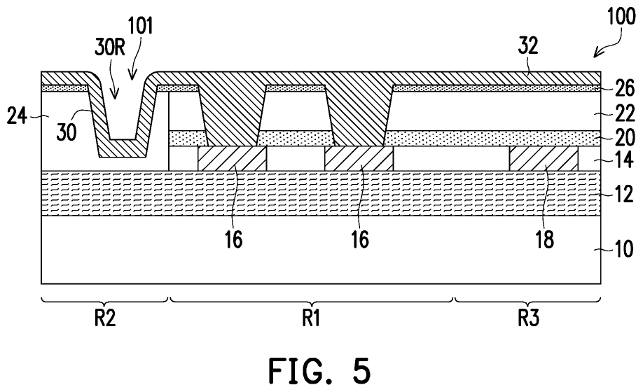

Referring to FIG. 5, a conductive material 32 is formed over the substrate 10 to fill the via opening 28 and the trench 30. The thickness of the conductive material 32 is sufficient to fill up the via opening 28 but not sufficient to completely fill the trench 30, and the conductive material 32 in the trench 30 forms a recess 30R.

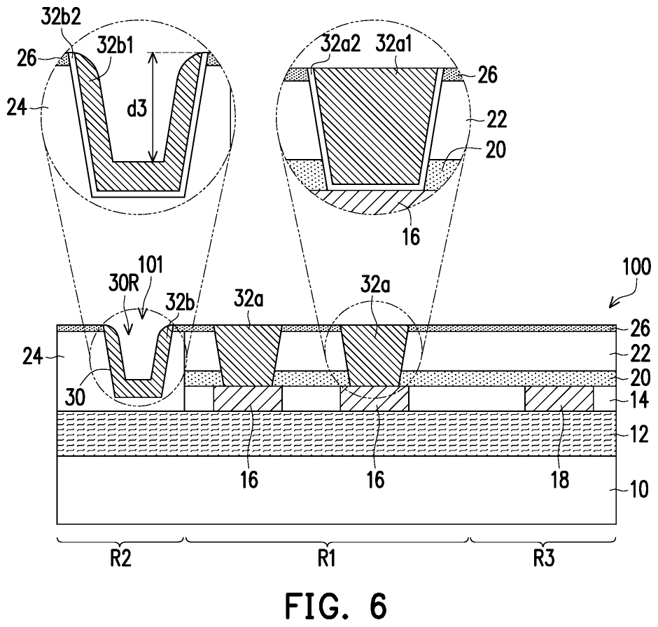

Referring to FIG. 6, a planarization process, such as a chemical mechanical polishing process, is performed to remove excess conductive material 32 on the stop layer 26, so as to form a via 32a in the via opening 28 and form a conductive layer 32b in the trench 30. In some embodiments, the top surface of the via 32a and the conductive layer 32b are coplanar with the top surface of the stop layer 26. The stop layer 26 is laterally connected to the conductive layer 32b and the via 32a. The dielectric layer 24 adjacent to the conductive layer 32b and the dielectric layer 22 adjacent to the via 32a have flat surfaces.

In some embodiments, the via 32a and the conductive layer 32b include a metal layer, such as tungsten. In some other examples, the via 32a and the conductive layer 32b include metal layers 32a1 and 32b1 and adhesive layers 32a2 and 32b2. For example, the metal layers 32a1 and 32b1 include tungsten, and the adhesive layers 32a2 and 32b2 include titanium nitride.

The thickness of the via 32a in the via opening 28 is greater than the thickness of the conductive layer 32b in the trench 30. In other words, the via 32a completely fills the via opening 28, while the conductive layer 32b does not completely fill the trench 30 and therefore a groove 30R is formed. The chemical mechanical polishing process has a high selectivity for the stop layer 26, so the stop layer 26 can serve as a polishing stop layer, and thus, the polishing loss of the dielectric layers 24 and 22 below the stop layer 26 can be reduced or avoided. Accordingly, the dielectric layer 24 can substantially maintain its original thickness and height, so that the groove 30R has a sufficient depth. The depth d3 of the groove 30R is greater than the depth required for the alignment mark 101, so that the detected signal has sufficient contrast. In some embodiments, the depth d3 of the recess 30R is greater than 500 angstroms. The disposition of the stop layer 26 can reduce the load on the via 32a and therefore reduce the polishing loss of the via 32a.

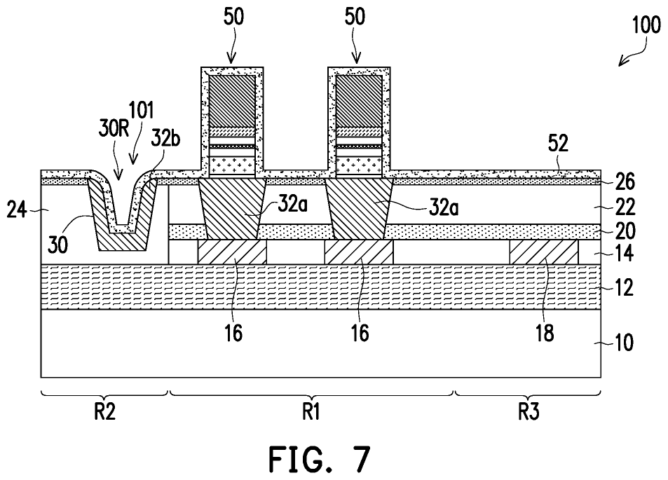

Referring to FIG. 7, one or more memory devices 50 are formed on the first region R1 of the substrate 10. The memory device 50 may be a resistive random access memory (RRAM), a magneto-resistive random access memory (MRAM), a phase change random access memory (PPCRAM) or the like. MRRAM, RRAM or PCRAM may include known multilayer materials. In some embodiments, the top layer of each memory device 50 includes an electrode, such as tantalum. Multiple memory devices 50 can be arranged in an array, but the disclosure is not limited thereto. The multiple memory devices 50 are electrically connected to the conductive lines 16 through the vias 32a.

The groove 30R of the conductive layer 32b has a sufficient depth, so the detected signal of the conductive layer 32b of the alignment mark 101 has sufficient contrast during the lithography process of patterning to form memory devices 50, and thus, the memory device 50 can be aligned with the via 32a.

Referring to FIG. 7, a spacer material 52 is formed on the substrate 10. The spacer material 52 covers the stop layer 26, the conductive layer 32b and the memory devices 50. The spacer material 52 can have a single-layer or multiple-layer structure. The spacer material 52 includes silicon nitride, silicon oxide or a combination thereof. The spacer material 52 conformally covers the stop layer 26, the conductive layer 32b and the memory devices 50, for example.

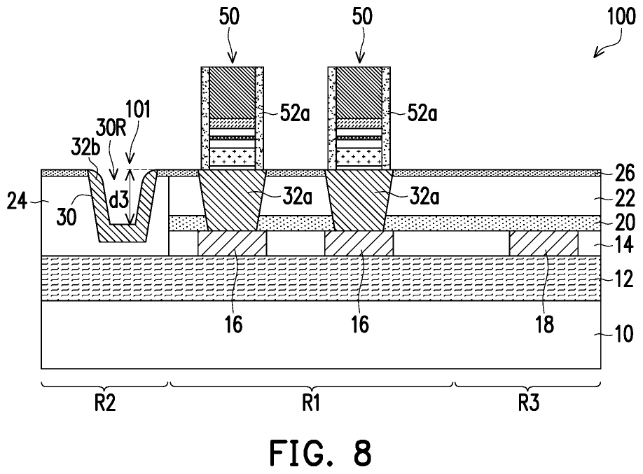

Referring to FIG. 8, an anisotropic etching process is performed to the spacer material 52, so as to form spacers 52a on the sidewalls of the memory devices 50. The spacer material on the stop layer 26 and the conductive layer 32b is removed, so the stop layer 26 and the conductive layer 32b are exposed. There is still a groove 30R in the conductive layer 32b, and the groove 30R still has the depth d3.

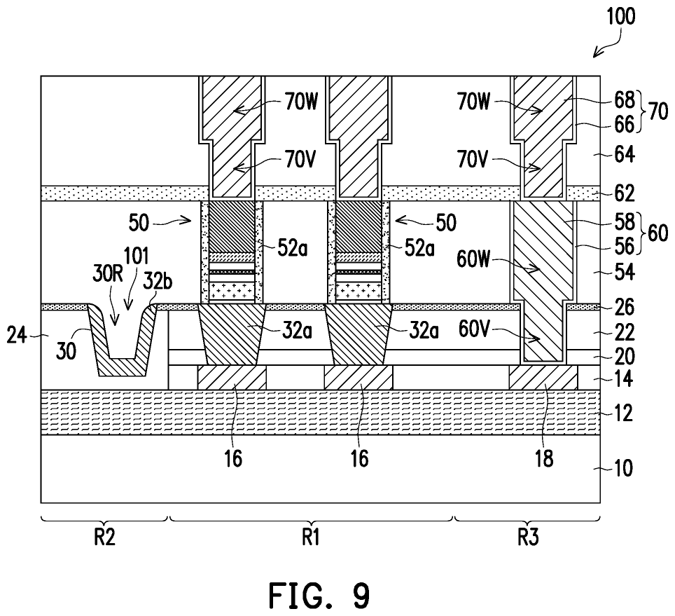

Referring to FIG. 9, the subsequent metallization process is performed. The metallization process includes forming a dielectric layer 54, forming one or more conductive features 60 in dielectric layer 54, forming a stop layer 62 and a dielectric layer 64, and forming conductive features 70 in the dielectric layer 64 and the stop layer 62. The dielectric layers 54 and 64 include silicon oxide, a low dielectric constant material layer, an ultra-low dielectric constant material layer or a combination thereof. The stop layer 62 includes nitrogen-doped silicon carbide, silicon nitride, silicon oxynitride, aluminum oxide or a combination thereof.

The conductive features 60, 70 may include barrier layers 56, 66 and metal layers 58, 68, respectively. The conductive features 60, 70 include vias 60V, 70V and conductive lines 60W, 70W, respectively. The via 60V is formed in the stop layer 20, the dielectric layer 22 and the stop layer 26. The conductive line 60W is formed in the stop layer 62 and the dielectric layer 54. The conductive lines 70W are formed in the dielectric layer 64. The via 70V connected to conductive line 60W is formed in dielectric layer 64. The vias 70V connected to the memory devices 50 are formed in the dielectric layer 64 and the stop layer 62.

The conductive features 60, 70 may be formed using a single damascene process, a dual damascene process, a combination thereof, or any known method. For example, the method of forming the conductive feature 60 includes the following steps. First, lithography and etching processes are performed to form one or more dual damascene openings (not shown). The dual damascene opening includes a trench and an via opening. The trench is located in the dielectric layer 54. The via opening is located in the stop layer 26, the dielectric layer 22 and the stop layer 20. Then, a conductive material is filled in the dual damascene opening. The conductive material includes a barrier material and a metal material. Afterwards, a chemical mechanical polishing process is performed to remove the excess barrier and metal materials to form the barrier layer 56 and the metal layer 58.

The groove 30R of the conductive layer 32b has a sufficient depth after forming the memory devices 50 and the spacers 52a, so the detected signal of the conductive layer 32b of the alignment mark 101 has sufficient contrast during the lithography process of forming the dual damascene opening, and thus, the via 60V can be aligned with the conductive line 18.

In the embodiment in which the third region R3 is a non-scribing line region, the conductive layer 32b can still remain in the chip after the subsequent dicing process. In the embodiment in which the third region R3 is a scribe line region, the conductive layer 32b will be cut off in the subsequent dicing process and cannot exist in the chip.

Based on the above, in the embodiment of the present disclosure, a stop layer disposed on the dielectric layer can avoid or reduce the polishing loss of the conductive layer of the alignment mark. Accordingly, the conductive layer of the alignment mark has a groove with a sufficient depth, so that the detected signal has sufficient contrast.

Although the present disclosure has been disclosed above with the embodiments, it is not intended to limit the present disclosure. Anyone with ordinary knowledge in the technical field may make some changes and modifications without departing from the spirit and scope of the present disclosure. The scope of protection of the present disclosure should be defined by the scope of the appended patent application.

What is claimed is:

1. A semiconductor device, comprising:
a dielectric layer disposed on the substrate;
a stop layer disposed on the dielectric layer;
a via extending in the stop layer and the dielectric layer; and
a memory device disposed on and electrically connected to the via.

2. The semiconductor device according to claim 1, further comprising:
an alignment mark, comprising:
a trench disposed in the dielectric layer, wherein a bottom surface of the trench is lower than a bottom surface of the via; and
a conductive layer covering a sidewall and a bottom surface of the trench,
wherein the conductive layer in the trench has a groove.

3. The semiconductor device according to claim 2, wherein the stop layer is connected to the conductive layer and the via.

4. The semiconductor device according to claim 2, wherein a top surface of the conductive layer, a top surface of the stop layer, and a top surface of the via are coplanar.

5. The semiconductor device according to claim 2, wherein a first top surface of the dielectric layer adjacent to the conductive layer and a second top surface of the dielectric layer adjacent to the via are in coplanar.

6. The semiconductor device according to claim 2, wherein the dielectric layer adjacent to the conductive layer and the dielectric layer adjacent to the via have flat surfaces.

7. The semiconductor device according to claim 2, wherein a depth of the groove is greater than 500 angstroms.

8. The semiconductor device according to claim 2, wherein a ratio of a depth of the trench to a depth of the via is greater than 1.5.

9. The semiconductor device according to claim 1, further comprising:
a plurality of spacers disposed on sidewalls of the memory device.

10. A method of fabricating a semiconductor device, comprising:
forming a first dielectric layer on a substrate;
forming a stop layer on the first dielectric layer;
forming a via opening and a trench for an alignment mark in the stop layer and the first dielectric layer;
forming a conductive material on the substrate, the conductive layer filling up the via opening and filling in the trench;
performing a planarization process to remove the conductive material above the stop layer, so as to form a via in the via opening and form a conductive layer in the trench, wherein the conductive layer in the trench has a groove therein; and
forming a memory device on the via.

11. The method according to claim 10, wherein a bottom surface of the trench is lower than a bottom surface of the via opening.

12. The method according to claim 10, further comprising forming a plurality of spacers on sidewalls of the memory device.

13. The method according to claim 12, further comprising forming a metal interconnection line over the substrate by using the conductive layer in the trench as an alignment mark.

14. The method according to claim 10, wherein the stop layer is connected to the conductive layer and the via.

15. The method according to claim 10, wherein a top surface of the conductive layer, a top surface of the stop layer, and a top surface of the via are coplanar.

16. The method according to claim 10, wherein a top surface of a portion of the first dielectric layer adjacent to the conductive layer and a top surface of another portion of the first dielectric layer adjacent to the via are coplanar.

17. The method according to claim 10, wherein the first dielectric layer adjacent to the conductive layer and the first dielectric layer adjacent to the via have flat surfaces.

18. The method according to claim 10, wherein the conductive layer covers a bottom surface and a sidewall of the trench, and a height difference between the conductive layer on the bottom surface of the trench and the conductive layer on top of the sidewall of the trench is greater than 500 angstroms.

19. The method according to claim 10, wherein a ratio of a depth of the trench to a depth of the via opening is greater than 1.5.

20. The method according to claim 10, wherein the trench is located in a scribe line region of the substrate.
